(19) United States
(12) Patent Application Publication
(10) Pub. No.: US 2015/0055314 A1
(43) Pub. Date: Feb. 26, 2015

(54) MOUNTING ASSEMBLY FOR CHIP CARD AND PORTABLE ELECTRONIC DEVICE USING SAME

(71) Applicants: FIH (Hong Kong) Limited, Kowloon (HK); SHENZHEN FUTAIHONG PRECISION INDUSTRY CO., LTD., Shenzhen (CN)

(72) Inventor: YAN-LING GAO, Shenzhen (CN)

(73) Assignees: FIH (Hong Kong) Limited, Kowloon (HK); SHENZHEN FUTAIHONG PRECISION INDUSTRY CO., LTD., Shenzhen (CN)

(21) Appl. No.: 14/061,323

(22) Filed: Oct. 23, 2013

(30) Foreign Application Priority Data
Aug. 21, 2013 (CN) 2013103647663

(51) Int. Cl. H05K 7/14

(52) U.S. Cl. CPC H05K 7/1461
USPC 361/807; 312/319.1

(57) ABSTRACT

A mounting assembly for a chip card used in a portable electronic device includes a cover, an operating element, and a receiving member for receiving the chip card. One end of the operating element is slidably received in the cover, and the other end of the operating element is elastically resisted between the receiving member and the cover and is connected to the receiving member. The cover is pressed to expose the operating element and the operating element is pulled to allow the receiving member to move out of the portable electronic device.

### BACKGROUND

1. Technical Field

The disclosure generally relates to mounting assemblies for chip card, and particularly to a mounting assembly and a portable electronic device using the same.

2. Description of the Related Art

Mounting assemblies are usually used in portable electronic devices for mounting chip cards. A typical mounting assembly has complex structures and takes up too much space.

Therefore, there is room for improvement within the art.

### BRIEF DESCRIPTION OF THE DRAWINGS

Many aspects of an exemplary mounting assembly can be better understood with reference to the following drawings. The components in the drawings are not necessarily drawn to scale, the emphasis instead being placed upon clearly illustrating the principles of the exemplary mounting assembly. Moreover, in the drawings, like reference numerals designate corresponding in position parts throughout the several views. Wherever possible, the same reference numbers are used throughout the drawings to refer to the same or like elements of an embodiment.

FIG. 1 is a schematic view of a mounting assembly used in a portable electronic device, according to an exemplary embodiment.

FIG. 2 is an exploded view of the portable electronic device shown in FIG. 1.

FIG. 3 is an exploded view of the mounting assembly shown in FIG. 1.

FIG. 4 is a schematic view of a housing shown in FIG. 2.

FIG. 5 is a schematic view of a base frame shown in FIG. 2.

FIG. 6 is a schematic view showing the using state of the mounting assembly shown in FIG. 1.

### DETAILED DESCRIPTION

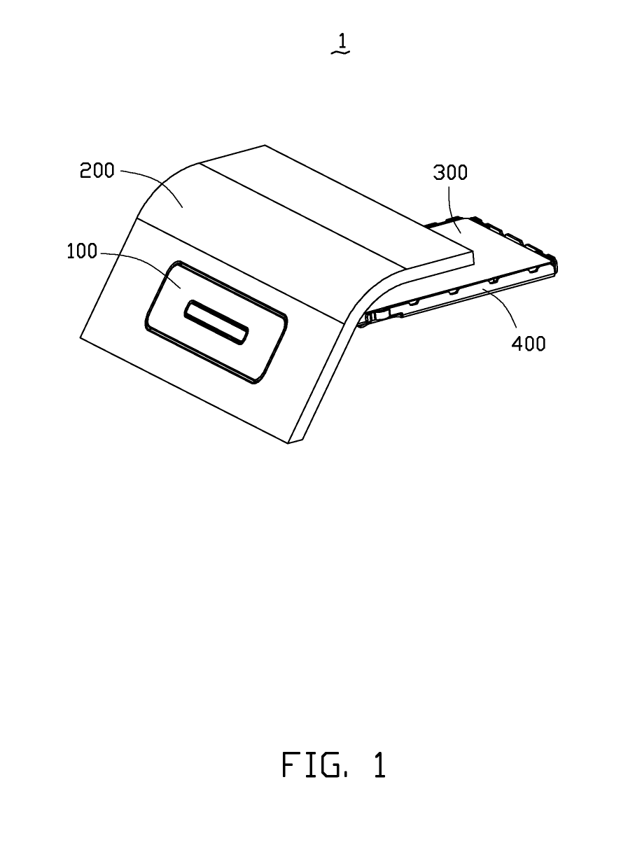

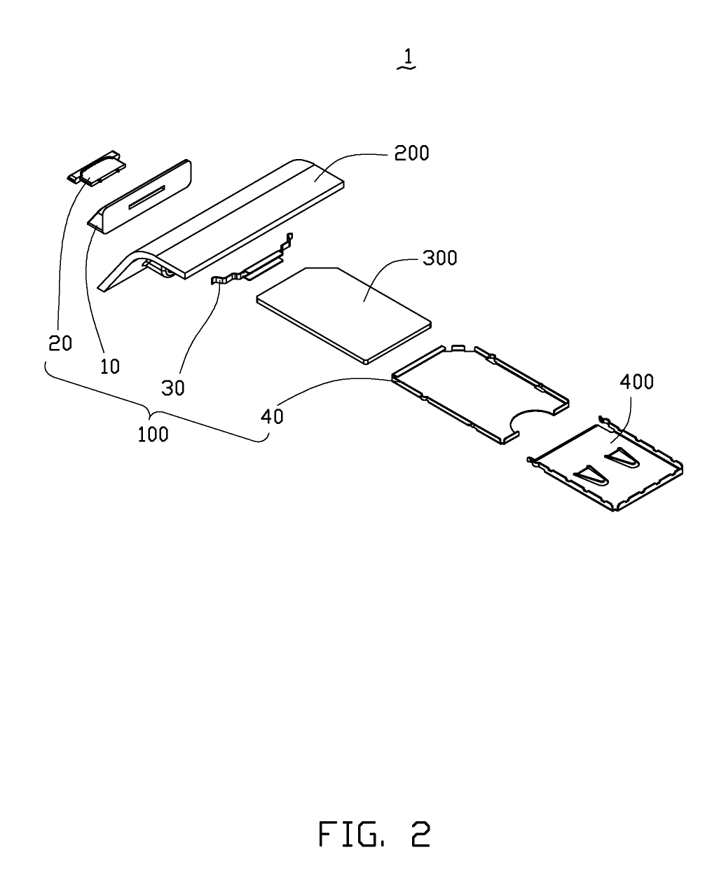

FIG. 1 and FIG. 2 show a mounting assembly 100 used in a portable electronic device 1, such as a mobile phone, a personal digital assistant, or a tablet computer. The portable electronic device 1 includes the mounting assembly 100, a housing 200, a chip card 300 and a base frame 400. The chip card 300 is received in the mounting assembly 100. The mounting assembly 100 is slidably mounted in the base frame 400. The base frame 400 is fixed in the housing 200. In this embodiment, the chip card 300 is a subscriber identity module (SIM) card.

The mounting assembly 100 includes a cover 10, a connecting member 20, an elastic member 30, and a receiving member 40. The connecting member 20 is slidably received in the cover 10 and is engaged with the elastic member 30 and the receiving member 40. The chip card 300 is received in the receiving member 40, and a chip (not shown) of the chip card 300 is exposed out of the receiving member 40. The receiving member 40 is received in the base frame 400.

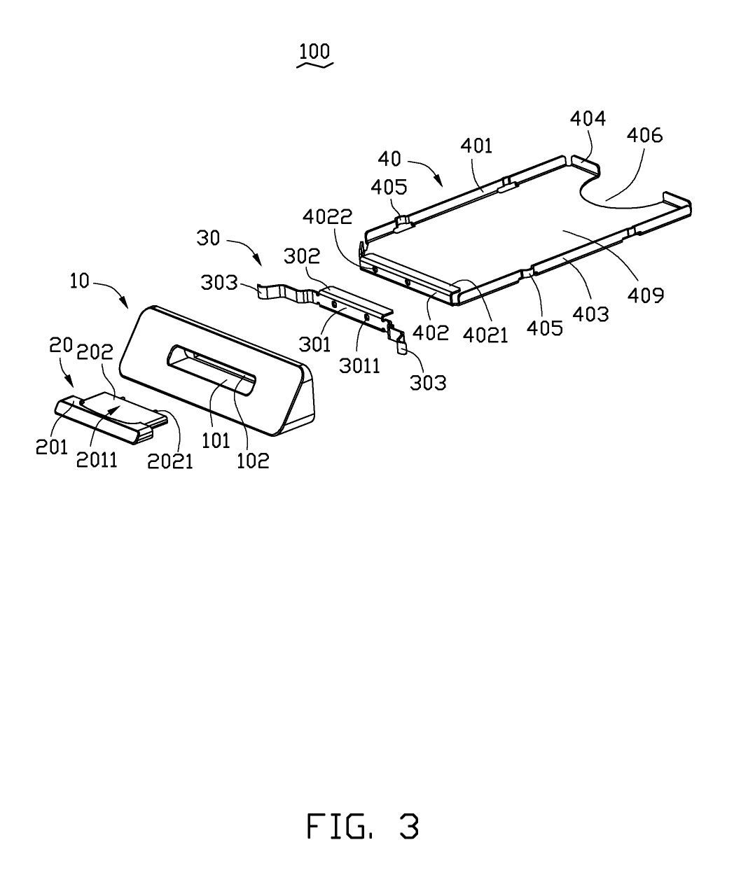

FIG. 3 is an exploded view of the mounting assembly 100. The cover 10 is substantially a triangular pyramid and defines a groove 101. A bottom wall (not labeled) of the groove 101 defines a through hole 102. The connecting member 20 includes an operating portion 201 and a fixing plate 202 extending from a side of the operating portion 201. A joint between the operating portion 201 and the fixing plate 202 defines an arcuate recess 2011. Two posts 2021 spaced apart from each other are located on an end surface of the fixing plate 202.

The elastic member 30 includes a main body 301, two parallel latching portions 302 and two opposite elastic arms 303. The main body 301 defines two spaced apart holes 3011. The two latching portions 302 are perpendicularly connected to the main body 301 and are spaced apart by the main body 301. Each elastic arm 303 is connected to an end of the main body 301. In this embodiment, the elastic arm 303 is a bent sheet and the elastic member 30 is made of metal.

The receiving member 40 has a shape similar to the chip card 300 and is configured for receiving the chip card 300. The receiving member 40 includes a base plate 409, a first peripheral wall 401, a second peripheral wall 402, a third peripheral wall 403 and a fourth peripheral wall 404. The first peripheral wall 401, the second peripheral wall 402, the third peripheral wall 403 and the fourth peripheral wall 404 are perpendicularly connected to the base plate 409. The first peripheral wall 401 is parallel to the third peripheral wall 403, and the second peripheral wall 402 is parallel to the fourth peripheral wall 404. Two clasp portions 405 are respectively formed on the first peripheral wall 401 and the third peripheral wall 403, and the clasp portion 405 on the first peripheral wall 401 is opposite to the clasp portion 405 on the third peripheral wall 403. The second peripheral wall 402 defines two spaced apart apertures 4022 corresponding in position to the holes 3011. A stopper portion 4021 extends from a free end of the second peripheral wall 402. The fourth peripheral wall 404 and the base plate 409 define a semicircular opening 406. In this embodiment, the receiving member 40 is made of metal.

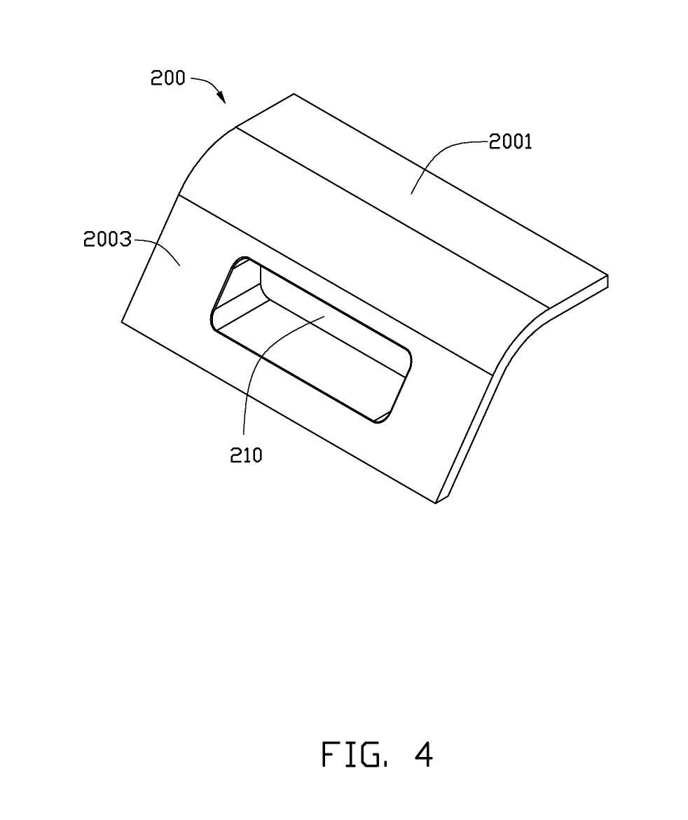

FIG. 4 shows that the housing 200 includes a base wall 2001 and a sidewall 2003 connected to the base wall 2001. The sidewall 2003 defines a receiving groove 210 for receiving the cover 10. The base frame 400 is located adjacent to the receiving groove 210.

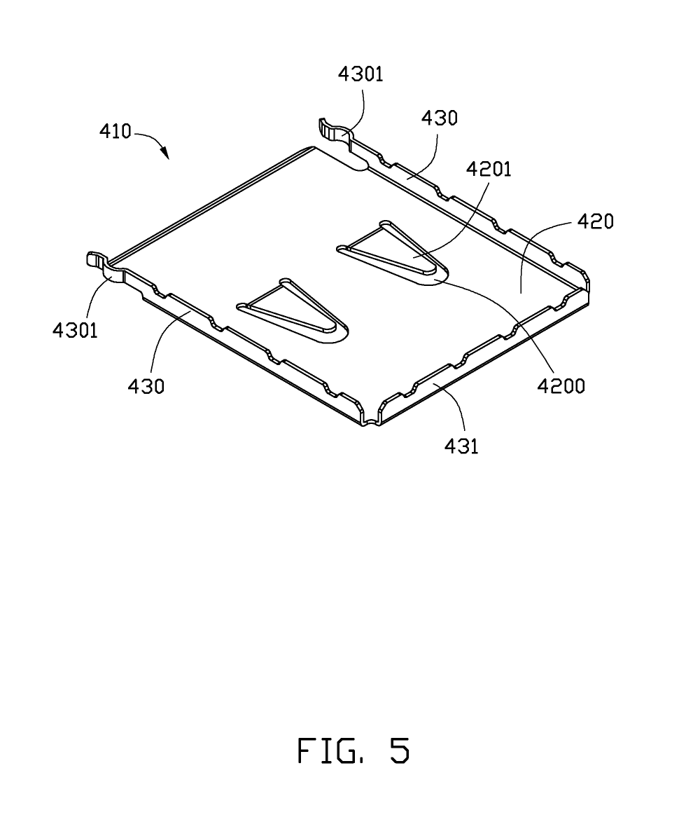

FIG. 5 shows the base frame 400 including a board 420, two opposite first sidewalls 430, and a second sidewall 431 connected to the two first sidewalls 430. The two first sidewalls 430 and the second sidewall 431 are perpendicularly connected to the board 420. The two first sidewalls 430 and the second sidewall 431 define an entrance 410. The receiving member 40 is slidably received in the base frame 400 through the entrance 410. The board 420 defines two U-shaped slots 4200 to form two strips 4201. Each of the two first sidewalls 430 defines an engaging groove 4301 engaging with the clasp portion 405.

The assembly process of the mounting assembly 100 may be as follows:

The cover 10 is slidably received in the receiving groove 210, and an external surface of the cover 10 is coplanar (i.e., flush) with an external surface of the housing 200. The operating portion 201 of the connecting member 20 is slidably received in the groove 101, and an external surface of the operating portion 201 is coplanar (i.e., flush) with an external surface of the cover 10. The fixing plate 202 passes through the through hole 102 of the cover 10, and the two posts 2021 pass through the holes 3011 of the elastic member 30 and the apertures 4022 of the receiving member 40. In this embodiment, the elastic member 30 and the receiving member 40 are fixed on the posts 2021 by welding. The second peripheral wall 402 is clamped between the two latching portions 302, and the two elastic arms 303 resist the cover 10.

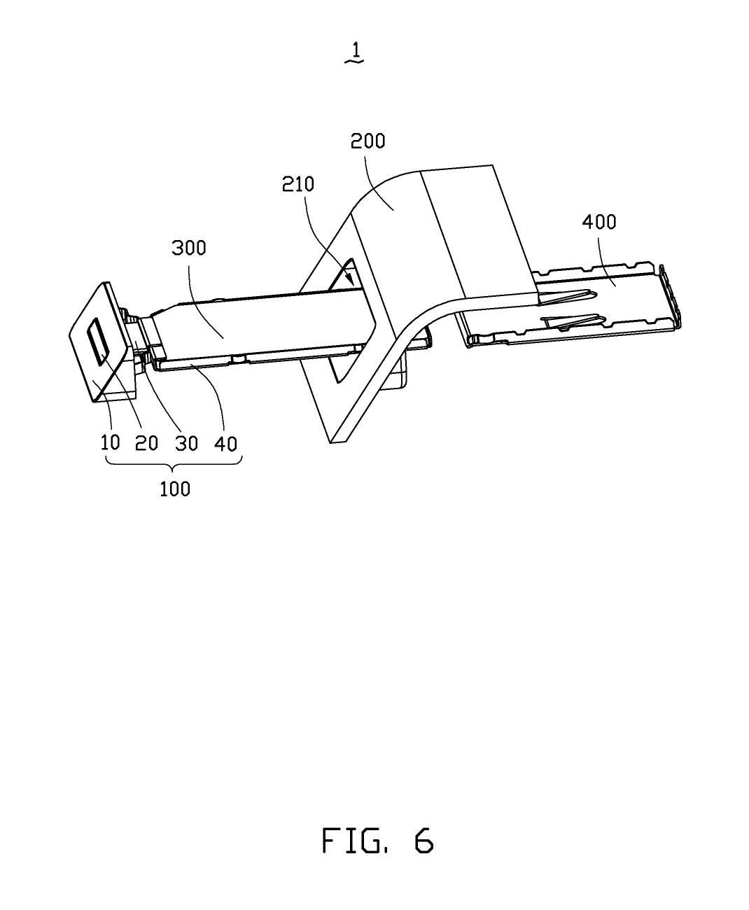

FIG. 6 shows the use of the mounting assembly 100. The chip card 300 is received in the receiving member 40. The stopper portion 4021 resists one end of the chip card 300. The receiving member 40 with the chip card 300 is received in the base frame 400 through the entrance 410. The two clasp portions 405 are respectively received in the engaging grooves 4301. The two strips 4201 resist against the receiving member 40 to allow the chip card 300 to be electronically connected to a printed circuit board (not shown) of the portable electronic device 1. Wherein when user needs to take the chip card 300 out of the portable electronic device 1, pressing the cover 10 to deform the elastic arms 303, and the connecting member 20 is exposed out of the cover 10. The user catches the recess 2011 of the connecting member 20 and pulls the connecting member 20 away from the housing 200 to separate the clasp portions 405 from the engaging grooves 4301. Further pulling the connecting member 20 to move the receiving member 40 out of the base frame 400 until the receiving member 40 passes through the receiving groove 210, then the chip card 300 is exposed out of the housing 200. The user can pick up the chip card 300 from the receiving member 40 via the opening 406.

The mounting assembly 100 has simple structure and it is convenient to use the mounting assembly 100 for loading or unloading the chip card 300.

It is to be understood, the connecting member 20 and the elastic member 30 are referred to an operating element. One end of the operating element is slidably received in the cover 10, and the other end of the operating element is elastically resisted between the receiving member 40 and the cover 10 and is connected to the receiving member 40.

In another exemplary embodiment, the base frame 400 can be omitted.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in the matters of shape, size, and arrangement of parts within the principles of exemplary disclosure to the full extent indicated by the broad general meaning of the terms in which the appended claims are expressed.

What is claimed is:

1. A mounting assembly for a chip card used in a portable electronic device, the mounting assembly comprising:
a cover;
an operating element; and
a receiving member for receiving the chip card;
wherein one end of the operating element is slidably received in the cover, and the other end of the operating element is elastically resisted between the receiving member and the cover and is connected to the receiving member; wherein when taking out of the chip card, the cover is pressed to expose the operating element and the operating element is pulled to allow the receiving member to move out of the portable electronic device.

2. The mounting assembly as claimed in claim 1, wherein the operating element comprises a connecting member and an elastic member, the connecting member is slidably received in the cover and is engaged with the elastic member and the receiving member; the elastic member is elastically resisted between the receiving member and the cover and is connected to the receiving member.

3. The mounting assembly as claimed in claim 2, wherein the connecting member comprises an operating portion and a fixing plate extending from a side of the operating portion; the cover defines a groove, a bottom wall of the groove defines a through hole;
the operating portion is slidably received in the groove, the fixing plate passes through the through hole of the cover to connect to the elastic member and the receiving member.

4. The mounting assembly as claimed in claim 3, wherein a joint between the operating portion and the fixing plate defines an arcuate recess.

5. The mounting assembly as claimed in claim 3, wherein two posts spaced apart from each other are located on an end surface of the fixing plate; the elastic member defines two holes and the receiving member defines two apertures; the two posts pass through the holes of the elastic member and the apertures of the receiving member.

6. The mounting assembly as claimed in claim 3, wherein the elastic member comprises a main body, two parallel latching portions and two opposite elastic arms; the two latching portions are perpendicularly connected to the main body and are spaced apart by the main body; each elastic arm is connected to an end of the main body.

7. The mounting assembly as claimed in claim 6, wherein each of the elastic arms is a bent sheet.

8. The mounting assembly as claimed in claim 6, wherein the receiving member comprises a base plate, a first peripheral wall, a second peripheral wall, a third peripheral wall and a fourth peripheral wall; the first peripheral wall, the second peripheral wall, the third peripheral wall and the fourth peripheral wall are perpendicularly connected to the base plate; a stopper portion extends from a free end of the second peripheral wall; the fourth peripheral wall and the base plate define an opening.

9. A portable electronic device comprising:
a housing defining a receiving groove; and
a mounting assembly for a chip card is slidably received in the housing, the mounting assembly comprising:
a cover slidably received in the receiving groove;
an operating element; and
a receiving member for receiving the chip card;
wherein one end of the operating element is slidably received in the cover, and the other end of the operating element is elastically resisted between the receiving member and the cover and is connected to the receiving member; wherein when taking out of the chip card, the cover is pressed to expose the operating element and the operating element is pulled to allow the receiving member to move out of the housing.

10. The portable electronic device as claimed in claim 9, wherein the operating element comprises a connecting member and an elastic member, the connecting member is slidably received in the cover and is engaged with the elastic member and the receiving member; the elastic member is elastically resisted between the receiving member and the cover and is connected to the receiving member.

11. The portable electronic device as claimed in claim 10, wherein the connecting member comprises an operating portion and a fixing plate extending from a side of the operating portion; the cover defines a groove, a bottom wall of the groove defines a through hole; the operating portion is slidably received in the groove, the fixing plate passes through the through hole of the cover to connect to the elastic member and the receiving member.

12. The portable electronic device as claimed in claim 11, wherein a joint between the operating portion and the fixing plate defines an arcuate recess.

13. The portable electronic device as claimed in claim 11, wherein two posts spaced apart from each other are located on an end surface of the fixing plate; the elastic member defines two holes and the receiving member defines two apertures; the two posts pass through the holes of the elastic member and the apertures of the receiving member.

14. The portable electronic device as claimed in claim 11, wherein the elastic member comprises a main body, two parallel latching portions and two opposite elastic arms; the two latching portions are perpendicularly connected to the main body and are spaced apart by the main body; each elastic arm is connected to an end of the main body.

15. The portable electronic device as claimed in claim 14, wherein each of the elastic arms is a bent sheet.

16. The portable electronic device as claimed in claim 14, wherein the receiving member comprises a base plate, a first peripheral wall, a second peripheral wall, a third peripheral wall and a fourth peripheral wall; the first peripheral wall, the second peripheral wall, the third peripheral wall and the fourth peripheral wall are perpendicularly connected to the base plate; a stopper portion extends from a free end of the second peripheral wall; the fourth peripheral wall and the base plate define an opening.

17. The portable electronic device as claimed in claim 9, further comprises a base frame fixed in the housing, the receiving member is slidably mounted in the base frame.

18. The portable electronic device as claimed in claim 17, wherein the base frame comprises a board, two opposite first sidewalls, and a second sidewall connected to the two first sidewalls; the two first sidewalls and the second sidewall are perpendicularly connected to the board, and the two first sidewalls and the second sidewall define an entrance.

19. The portable electronic device as claimed in claim 18, wherein the board defines two U-shaped slots to form two strips resisting against the receiving member.
